(19) United States
(12) Patent Application Publication
(10) Pub. No.: US 2026/0243830 A1
(43) Pub. Date: Aug. 20, 2026

(54) SYSTEMS AND METHODS FOR MOTOR FAULT DETECTION

(71) Applicant: Mitsubishi Electric Research Laboratories, Inc., Cambridge, MA (US)

(72) Inventors: Dehong Liu, Lexington, MA (US); Peikun Guo, Boston, MA (US); Bingnan Wang, Belmont, MA (US); Yebin Wang, Cambridge, MA (US)

(73) Assignee: Mitsubishi Electric Research Laboratories, Inc., Cambridge, MA (US)

(21) Appl. No.: 19/053,786

(22) Filed: Feb. 14, 2025

(51) Int. Cl. G01R 31/34

(52) U.S. Cl. CPC G01R 31/343; G01R 31/346

(57) ABSTRACT

A method for motor fault detection comprises acquiring sensor data from each sensor of a plurality of sensors associated with a motor. Each sensor of the plurality of sensors provides data corresponding to a unique modality. The method further comprises extracting features from the sensor data of each sensor and mapping the extracted features to a shared latent space using a deep generalized canonical correlation analysis model that aligns the features by learning nonlinear transformations that maximize correlations among the sensor data of different sensors. An attention-based fusion mechanism is applied to the aligned features to dynamically compute attention weights for each sensor modality based on a relevance of a respective sensor modality to a fault detection task. The method further comprises generating a fused feature representation by aggregating the aligned features weighted by the attention-based fusion mechanism and generating motor fault data based on the fused feature representation.

### TECHNICAL FIELD

The present disclosure is generally related to systems and methods for monitoring motor health condition, and more particularly to deep learning-based approaches for aligning multi-modal sensor data for motor fault detection.

### BACKGROUND

Rotating machinery, including induction motors, form the backbone of industrial operations across sectors such as manufacturing, energy, and transportation. Motors are integral to numerous industrial applications and electrified transportation systems. For example, induction motors are widely used in various industries due to their robust design, low maintenance requirements, and cost-effective operation. Such machines rely on components such as bearings, to ensure efficient and reliable operation. However, such machines often operate under harsh conditions such as high ambient temperature, high moisture, and overload. Such adverse environments can lead to various motor faults, such as bearing wear, insulation aging, and eccentricity, etc. These faults pose significant risks, including equipment downtime, safety hazards, and increased maintenance costs. Despite advancements in technology, accurate and reliable detection of motor faults remains a challenge, particularly under variable operating conditions and in the early stages of fault development.

Currently available solutions are not sufficient for making an efficient analysis of motors faults. For example, physical-model-based approaches that aim to extract fault signals from sensing data using domain knowledge, work well only for motors operating at steady status with a constant load and rotating speed. Signal processing and machine learning based approaches such as artificial neural networks (ANN), principal component analysis (PCA), and support vector machines (SVM) struggle under diverse operating conditions and noisy environments. Accordingly, robust and efficient approaches for detecting motor faults and determining the severity levels of the faults are still desired.

### SUMMARY

Various example embodiments are directed towards detecting motor faults in early stages of development of such faults by analyzing multimodal data from various sensors. In this regard, some embodiments provide deep learning-based approaches for aligning multi-modal sensor data to improve estimation of a motor's health condition. It is a realization of some embodiments that sensor data of different modalities may be used individually to detect a distinct fault type corresponding to each modality. However, some embodiments also recognize that a single modality sensor data may not be sufficient for detecting multiple fault types. For example, while current signals may be valuable in detecting eccentricity faults, they are barely useful in detecting bearing surface wear. On the other hand, vibration signals may be valuable in detecting mechanical faults such as bearing fault, but not in detecting electrical faults such as insulation faults and short-circuit faults. Accordingly, various embodiments are based on the realization that integration of data from multiple sensors provides a comprehensive view of the motor's health condition, capturing diverse aspects of its operation. By combining these modalities, it is possible to achieve better detection performance than that using any single modality alone.

Inspired by such realizations, various example embodiments are based on multi-sensor data fusion utilizing Multiview representation learning (MVRL) methods. It is a realization of various embodiments that a representation that can explain multiple data views is more likely to capture the essential characteristics than one that only fits a single view. In the context of motor fault detection, various sensor data such as stator current, vibration, and velocity, etc., may be considered as different views of the motor fault, but highly nonlinearly correlated. However, available Multiview learning techniques rely on Canonical Correlation Analysis (CCA)—a classical statistical method using linear transformations. Even deep learning-based CCA methods learn nonlinear transformations for better performance but mainly focus on two-view data.

To address the aforementioned problems, various example embodiments incorporate Deep Generalized CCA (DGCCA) with attention-based fusion to fuse features of different sensors effectively. Such a DGCCA-based framework for motor fault detection can operate using nonlinearly correlated, multi-modal sensor data, which may be difficult to analyze using physical models, for improved detection performance. To arrive at the solution of using DGCCA for motor fault detection, various embodiments are based on recognizing a fundamental challenge: while sensor data from different modalities—such as vibration, current, and velocity—appear to be independent, they are in fact interconnected. Each sensor measures a unique aspect of the motor's behavior, yet these measurements are responses to the same underlying fault conditions. For example, a bearing fault manifests as mechanical vibrations, but it can also subtly impact the motor's current and rotor velocity.

Although these effects are distinct when viewed individually, they share a hidden relationship that ties them together. The inventor recognized that this relationship is not immediately apparent in the raw data and must be uncovered in a shared, latent space where the true nature of the correlation emerges. This recognition stems from an understanding of how faults propagate through a system. A fault-such as bearing wear induces oscillations in the motor, which cause mechanical imbalances that interact with the motor's electrical system. However, these interactions occur in complex, nonlinear ways, making it difficult to detect the fault using conventional methods. Existing approaches, such as physical models or linear techniques like the conventional Canonical Correlation Analysis (CCA), fail to capture these hidden relationships because they assume either steady-state conditions or simple linear dependencies between signals. The inventor understood Accordingly, some embodiments are based on the realization that a nonlinear approach is required to align the sensor data into a shared representation where fault-related features become prominent, while sensor-specific noise and irrelevant information are suppressed.

Building on this insight, various embodiments utilize DGCCA, an extension of deep learning-based CCA methods, which can process multiple sensor views simultaneously and learn nonlinear mappings from each view to a common latent space. By projecting the independent sensor data into this shared space, DGCCA identifies and maximizes the correlations that arise from the underlying fault condition. This approach allows each sensor to contribute its unique perspective while aligning those perspectives in a way that highlights their shared information. For example, vibration data may emphasize the mechanical aspects of a fault, while current data captures its subtle electrical effects. In the latent space, these signals reinforce each other, enabling a more accurate and robust detection of faults.

Some embodiments are based on another realization that not all sensor modalities contribute equally to fault detection under every condition. For instance, vibration data may be more relevant for detecting bearing faults, while current data is more indicative of eccentricity. To address this, various embodiments incorporate an attention-based fusion mechanism that dynamically assigns importance to each sensor modality based on its contribution to the fault detection task. This fusion ensures that the most informative features are emphasized, while less relevant signals are appropriately downweighed. The combination of DGCCA for feature alignment and attention-based fusion creates a system that is not only capable of uncovering hidden relationships but also adaptable to the specific nature of the fault being analyzed.

By recognizing the interconnected yet nonlinear nature of multi-sensor data and the limitations of existing methods, the embodiments arrive at a solution that leverages DGCCA to uncover the latent relationships among sensor signals. This insight enabled the creation of a fault detection system that integrates data from multiple sensors, aligns their features in a shared latent space, and fuses them intelligently to achieve superior accuracy and robustness. This approach transforms seemingly independent sensor data into a cohesive, fault-revealing representation, solving a long-standing challenge in motor fault detection.

In order to achieve the aforementioned objectives and advantages, various embodiments provide systems, methods, and apparatuses for motor fault detection using Deep Generalized Canonical Correlation Analysis.

Accordingly, one embodiment discloses a method for motor fault detection. The method comprises acquiring sensor data from a plurality of sensors monitoring a motor, wherein each sensor from the plurality of sensors provides data corresponding to a unique modality. The method for motor fault detection using multi-sensor data further comprises extracting features from each sensor's data from the plurality of sensors using one or more feature extraction models. The method for motor fault detection using multi-sensor data further comprises mapping the extracted features to a shared latent space using a Deep Generalized Canonical Correlation Analysis (DGCCA) model, wherein the DGCCA model aligns the features by learning nonlinear transformations that maximize correlations among the sensor data. The method for motor fault detection using multi-sensor data further comprises applying an attention-based fusion mechanism to the DGCCA-aligned features to dynamically compute attention weights for each sensor modality based on its relevance to a fault detection task. The method for motor fault detection using multi-sensor data further comprises generating a fused feature representation by aggregating the DGCCA-aligned features weighted by the attention mechanism. The method for motor fault detection using multi-sensor data further comprises classifying motor faults or estimating fault severity levels based on the fused feature representation.

In yet another example embodiment, a system for motor fault detection using multi-sensor data is provided. The system comprises a plurality of sensors configured to collect multi-modal data from a motor. The system for motor fault detection using multi-sensor data further comprises a feature extraction module configured to extract features from each sensor's data, wherein the features are time-domain or frequency-domain representations. The system for motor fault detection using multi-sensor data further comprises a Deep Generalized Canonical Correlation Analysis (DGCCA) module configured to align the extracted features into a shared latent space by learning nonlinear transformations that maximize correlations among the multi-modal data. The system for motor fault detection using multi-sensor data further comprises an attention-based fusion module configured to dynamically assign attention weights to the aligned features based on their relevance to a fault detection task. The system for motor fault detection using multi-sensor data further comprises a classification module configured to detect motor faults or estimate fault severity levels using the fused feature representation generated by the attention-based fusion module.

### BRIEF DESCRIPTION OF THE DRAWINGS

The presently disclosed embodiments will be further explained with reference to the following drawings. The drawings shown are not necessarily to scale, with emphasis instead generally being placed upon illustrating the principles of the presently disclosed embodiments.

FIG. 1A illustrates schematics of a system for fault detection in an induction motor, according to one embodiment;

FIG. 1B illustrates a flowchart of a method for system and methods for motor fault detection, according to some embodiments;

FIG. 2 shows an exemplar illustration of an induction motor monitored by different sensors, according to some embodiments;

FIG. 3 is a diagram of eccentricity severity level indicated by relative air gap, according to one embodiment;

FIG. 4 illustrates a cross sectional view of a rolling-element bearing of an electrical motor, according to one embodiment;

FIG. 5 illustrates various levels of bearing surface roughness severity of a bearing that supports the rotor shaft of an induction motor, according to one embodiment;

FIG. 6A shows a schematic description of real-world multi-view data of different modalities but correlated to each other when projected in the feature space, according to some embodiments;

FIG. 6B is a schematic diagram of a deep nueral network trained to correlate multi-view data in the feature space via generalized canonical correlation analysis, according to some embodiments;

FIG. 7 is a diagram illustrating a framework for multi-sensor motor fault detection, according to one embodiment;

FIG. 8 is a schematic diagram of a sensor fusion algorithm using a deep generalized canonical correlation analysis and attention fusion approach, according to some embodiments;

FIG. 9 illustrates a use case for motor fault detection in a factory automation system, according to one embodiment; and

FIG. 10 illustrates schematics of some components of a system for motor fault detection, according to one embodiment.

### DETAILED DESCRIPTION

The following description provides exemplary embodiments only, and is not intended to limit the scope, applicability, or configuration of the disclosure. Rather, the following description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the following description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like-reference numbers and designations in the various drawings may indicate like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine-readable medium. A processor(s) may perform the necessary tasks.

### Overview

Induction motors are indispensable in real-world applications. These motors play a pivotal role in driving machinery and ensuring the smooth operation of processes in various sectors, including manufacturing, transportation, and energy. Motors are critical components in various industrial and transportation systems due to their robustness, efficiency, and versatility. Mostly, motors are used for driving loads at variable speeds and therefore they are subject to severe mechanical stress, wear and tear, and often exposed to harsh operating conditions such as high ambient temperatures, excessive moisture, mechanical overloads, and fluctuating loads. Over time, these conditions can lead to structural as well as operational faults, including bearing wear, rotor eccentricity, and insulation aging. Such faults manifest in the performance of the motor, making the motor vulnerable to breakdown and unfit for the intended application.

In fact, motor faults are a leading cause of equipment failure, resulting in significant downtime, costly repairs, and safety hazards. For example, bearing failures are the common causes of downtime and maintenance in industrial equipment. Even minor defects in the bearing surface can propagate over time, leading to increased friction, heat generation, and vibrations that can affect the motor's overall performance. Some embodiments are based on the realization that systems for monitoring and diagnosis of bearing health are required for minimizing unexpected failures, reducing maintenance costs, and optimizing operational efficiency of induction machines. Early detection of such faults is essential to prevent catastrophic failures and to optimize maintenance schedules. It is a realization of some embodiments that the available fault detection methods rely only on single modality sensor data such as vibration or current analysis. As such, these approaches are insufficient in noisy and dynamic environments which are common in real-world applications. With the conventional approaches, capturing the complexity of motor behavior, particularly under variable operating conditions or during the early stages of fault development, is a challenge.

Some embodiments are based on the realization that one way to address the complexity of motor behavior includes integrating data from multiple sensors, such as vibration, current, and temperature sensors to achieve a comprehensive view of the motor's condition. However, such an integration of data from multiple sensors leads to complex datasets. Processing such large and complex datasets is challenging since fault detection requires a short turnaround. Some embodiments are based on another realization that advanced analytical techniques, including machine learning and deep learning, demonstrate potential in processing these complex datasets and detecting hidden patterns indicative of faults. However, current solutions utilize data in single modality which is not sufficient for making an efficient analysis of motors faults. Towards these ends, various example embodiments provide an advanced motor fault detection system that leverages multi-sensor data, integrates sophisticated analytical techniques, and provides reliable fault detection across diverse scenarios.

Some embodiments are based on another realization that not all sensor modalities contribute equally to fault detection under every condition. For instance, vibration data may be more relevant for detecting bearing faults, while current data is more indicative of eccentricity. Such a system ensures timely maintenance, reduces downtime, and enhances the safety and efficiency of motor operations.

Various embodiments address the challenge of detecting motor faults using multi-sensor data by employing Deep Generalized Canonical Correlation Analysis (DGCCA) and an attention-based fusion mechanism. This innovative approach recognizes that while sensor data from different modalities such as vibration, current, and velocity appear independent, they are deeply interconnected through their shared response to underlying fault conditions. For instance, a bearing fault induces mechanical vibrations that also affect the motor's current and rotor velocity.

To address this, some embodiments incorporate an attention-based fusion mechanism that dynamically assigns importance to each sensor modality based on its contribution to the fault detection task. This fusion ensures that the most informative features are emphasized, while less relevant signals are appropriately downweighed. The combination of DGCCA for feature alignment and attention-based fusion creates a system that is uncovering hidden relationships and adaptable to the specific nature of the fault being analyzed.

By recognizing the interconnected yet nonlinear nature of multi-sensor data and the limitations of existing methods, the embodiments arrive at a solution that leverages DGCCA to uncover the latent relationships among sensor signals. This insight enabled the creation of a fault detection system that integrates data from multiple sensors, aligns their features in a shared latent space, and fuses them intelligently to achieve accuracy and robustness. This approach transforms seemingly independent sensor data into a cohesive, fault-revealing representation, solving a long-standing challenge in motor fault detection.

The proposed solution outlines a comprehensive approach for motor fault detection using multi-sensor data. Some example embodiments present an advanced methodology for detecting motor faults by integrating data from multiple sensors, each capturing a distinct aspect of the motor's operation, such as vibration, current, or rotational speed. These sensors provide diverse insights into the motor's behavior, ensuring a holistic analysis of its condition. However, raw sensor data is often noisy and unstructured, necessitating the extraction of meaningful patterns or features that can effectively characterize potential faults. Feature extraction models play a role in this process, isolating relevant characteristics from each sensor's data to streamline the analysis.

To leverage the full potential of multi-sensor data, various example embodiments employ Deep Generalized Canonical Correlation Analysis (DGCCA) to align these features in a shared latent space. This approach uncovers the hidden relationships among different sensor modalities by learning nonlinear transformations, which maximize the correlations between the data streams. The latent space created by DGCCA provides a unified representation where fault-related features from all sensors are emphasized, while irrelevant or noisy elements are minimized, enabling a precise understanding of the underlying fault mechanisms.

Recognizing that not all sensor data contributes equally to fault detection under varying conditions, the system incorporates an attention-based fusion mechanism. This mechanism dynamically evaluates the importance of each sensor modality and assigns appropriate weights based on its relevance to the detection task. The weighted features from all sensors are then combined into a comprehensive representation that effectively encapsulates the fault-related information. This fused representation is subsequently analyzed to identify the type and severity of motor faults. By combining multi-sensor integration, nonlinear feature alignment through DGCCA, and dynamic attention-based fusion.

In the context of fault detection, some embodiments provide two distinct approaches to combining Deep Generalized Canonical Correlation Analysis (DGCCA) and attention mechanisms. The first approach involves creating separate DGCCA and attention modules for each fault type. For example, if there are five types of faults (e.g., bearing wear, eccentricity, insulation aging, etc.), the system uses five DGCCA models and five corresponding attention mechanisms. Each DGCCA module aligns features from multiple sensor modalities (such as current, vibration, and velocity) into a shared latent space that is specifically optimized for one fault type. The corresponding attention mechanism then dynamically weights the features based on their relevance to that fault. This approach allows the system to tailor both the alignment of sensor data and the feature weighting process to the unique characteristics of each fault type. As a result, the solution delivers highly optimized and fault-specific performance, as each DGCCA-attention pair is customized for its respective fault.

The other approach involves training a single DGCCA model to align sensor features for all fault types into a common latent space, combined with a multi-head attention mechanism. Here, the shared DGCCA captures generalizable correlations across all faults, while the multi-head attention module uses separate heads to emphasize different features depending on the fault being analyzed. For instance, one attention head may prioritize vibration and air gap data for detecting bearing faults, while another attention head focuses on current and velocity data for eccentricity faults. This approach reduces model complexity because only one DGCCA needs to be trained, but it achieves fault-specific feature weighting through the multi-head attention mechanism. By leveraging shared feature alignment with specialized attention heads, this strategy balances computational efficiency with the ability to adapt to diverse fault scenarios.

The key difference between these two approaches lies in how the DGCCA and attention modules are organized. The first method prioritizes specialization by creating entirely separate DGCCA-attention pairs for each fault, ensuring that both alignment and feature weighting are fine-tuned for individual fault types. In contrast, the second method uses a single DGCCA model to find a general latent space and relies on multi-head attention to adjust feature emphasis dynamically for each fault type. The choice between these approaches depends on the system's requirements: fault-specific optimization and accuracy favor the first method, while computational efficiency and model simplicity favor the second.

### Motor Control System and Method

It is an object of some embodiment to provide a system and a method for estimating not only the presence or absence of one or more faults in an induction motor but also the level of severity of the one or more faults. Additionally, some embodiments also provide measures for controlling the motor to combat or address the one or more faults. Some examples of the measures include altering the speed of the motor, changing the voltage, current, or phase of the input to the motor, or recommending modifications to the structure and design of the motor.

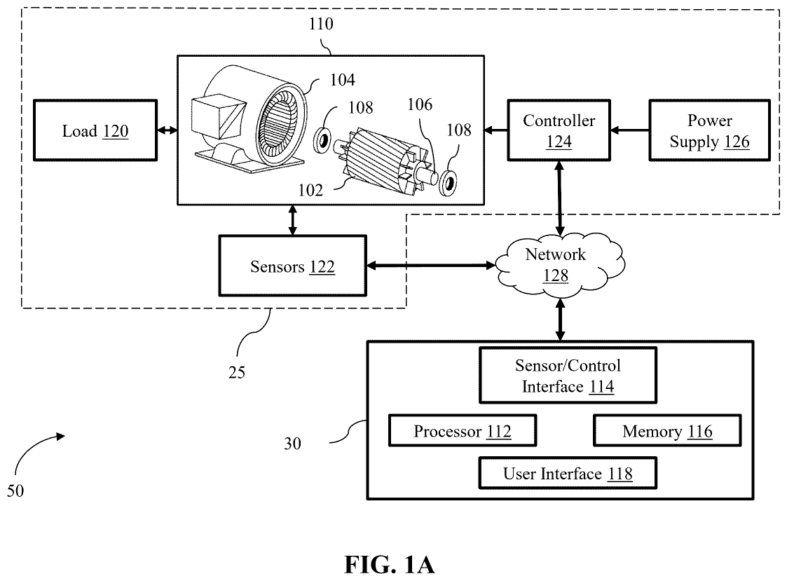

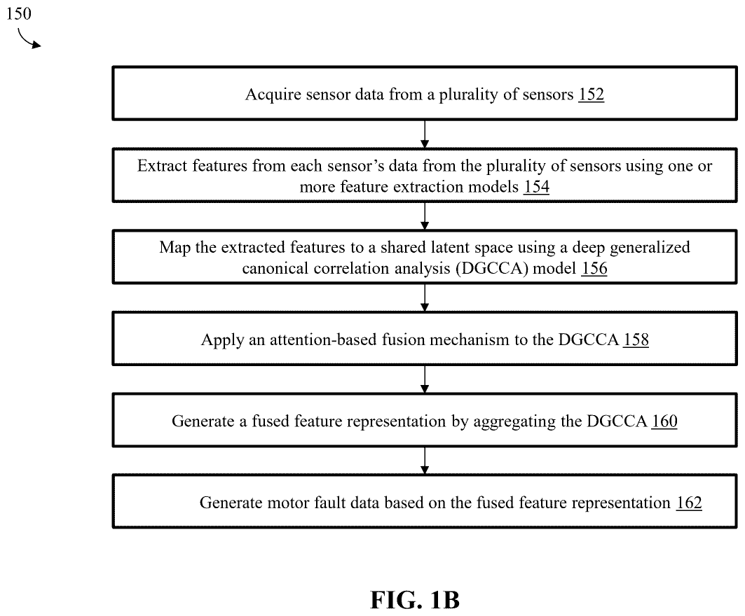

FIG. 1A illustrates a block diagram of a system 50 for fault detection in an induction motor 110, according to some embodiments. The system 50 may comprise a motor system 25 and a motor fault detection system 30. The motor system 25 and the motor fault detection system 30 may be communicatively coupled with each other through a network 128. The motor system 25 comprises an induction machine such as an induction motor 110 driving a load 120, a plurality of sensors 122, a motor controller 124, and a power supply 126. The motor fault detection system 30 comprises a sensor/control interface 114, a processor 112, a user interface 118, and a memory 116. In some embodiments, the motor controller 124 may receive input commands from a user or other computer program and compute reference values for the torque and speed of the motor 110.

The induction motor (system) 110 includes a rotor assembly 102, a stator assembly 104, a main shaft 106, and two main bearings 108. In this example, the induction motor 110 is a squirrel-cage induction motor, however, other configurations of the induction motor 110 may also be used.

The memory 116 stores the data hosting specialized modules that drive the intelligence of the system. The memory 116 store instructions that are executable by the system and any data that may be utilized by the methods and systems of the present disclosure. The memory 116 may include random access memory (RAM), read only memory (ROM), flash memory, or any other suitable memory systems. The memory 116 may be a volatile memory unit or units, and/or a non-volatile memory unit or units. The memory 116 may also be another form of computer-readable medium, such as a magnetic or optical disk. The memory 116 stores algorithms and data, including deep learning models such as those based on DGCCA (Deep Generalized Canonical Correlation Analysis) for analyzing sensor data, as well as historical fault data for pattern recognition and predictive maintenance.

Sensors 122 may be randomly or strategically placed to monitor the motor's operational parameters, such as vibration, current, temperature, and acoustic emissions. These sensors provide multimodal data, capturing distinct yet interconnected aspects of the motor's performance. For example, vibration sensors may aid in the detection of mechanical irregularities like bearing faults, while current sensors may aid in the identification of electrical anomalies, and temperature sensors may track overheating issues. Additionally, acoustic sensors may further enhance fault detection by capturing sound patterns indicative of specific problems. It may be contemplated that the sensors 122 may not be limited to the above-mentioned sensors; instead within the scope of this disclosure, they may as well include other sensors used with motors. The sensor data from the sensors 122 may be transmitted through a network 128 to the controller 124 that processes the incoming data.

The controller 124 may be powered by a power supply 126, ensuring consistent operation even under varying conditions. The controller 124 manages the coordination between data acquisition, analysis, and fault detection algorithms. The controller 124 may be used for monitoring and controlling the operation of the induction motor 110 in response to various inputs. For example, the controller 124 connected to the induction motor 110 may control the speed of the induction motor based on inputs received from the fault detection system 30 configured to acquire data pertaining to operating conditions of the induction motor 110 from the sensors 122. According to some embodiments, the electrical signal of the sensors 122 may be current and voltage values pertaining to the induction motor 110. For example, a current sensor may sense current data from one or more of the multiple phases of the induction motor 110. More specifically, in the case the induction motor 110 is a 3-phase induction motor, the current and voltage sensors sense the current and voltage data from the three phases of the 3-phase induction motor

The processor 112 is configured to execute instructions and perform advanced computations required for fault analysis. The processor 112 processes data received from sensors 122, which include vibration sensors, current sensors, temperature sensors, acoustic sensors, and optionally speed or position sensors. These sensors monitor various aspects of the motor's performance, such as mechanical vibrations, electrical current, heat levels, and sound patterns. By analyzing this multi-modal data, the processor identifies potential faults and optimizes the fault detection process.

The processor 112 employs advanced algorithms, including Deep Generalized Canonical Correlation Analysis (DGCCA), to map sensor data to a shared latent space, uncovering hidden relationships that indicate faults. Furthermore, the processor 112 integrates attention-based mechanisms to assign dynamic weights to sensor data based on relevance to fault detection. The processor 112 also manages predictive analytics, leveraging historical and real-time data to estimate fault severity and forecast potential failures, enabling proactive maintenance. In addition to data analysis, the processor 112 oversees the coordination of system components. The processor 112 communicates with the controller 124 to ensure seamless operation and interacts with the user interface 118 to provide real-time updates, fault alerts, and actionable insights.

The user interface 118 enables seamless interaction between the motor fault detection system 30 and operators, providing an intuitive platform for monitoring and control. The user interface 118 facilitates the output of real-time sensor data, fault detection outcomes, and actionable insights, ensuring that operators can effectively monitor the motor's performance and respond to potential issues promptly. Additionally, the user interface 118 allows operators and users to configure system settings, such as sensor parameters, alert thresholds, and fault classification preferences. The user interface 118 is designed to communicate with the processor 112, receiving processed data and transmitting commands or configurations as needed. Through its integration with the network 128, the user interface 118 ensures a smooth exchange of information with other system components, including the sensors 122, the controller 124, and the memory 116. The user interface 118 may be implemented through various platforms, such as touchscreens, desktop applications, or mobile devices, providing flexibility for on-site or remote monitoring.

The network 128 facilitates seamless communication between various components such as sensors 122, processor 112, controller 124, memory 116, and user interface 118. The network 128 enables data transmission, command execution, and coordination of system functions over wired or wireless channels, ensuring efficient and reliable operation. The network 128 may be implemented using multiple technologies to meet different operational requirements. For stationary systems, wired solutions such as Ethernet provide high-speed, secure, and stable connections. On the other hand, wireless technologies like Wi-Fi, Zigbee, Bluetooth, or cellular networks (e.g., 4G/5G) are ideal for applications requiring mobility, flexibility, or remote monitoring capabilities. The network 128 may include hardware components like routers, modems, or wireless transceivers, ensuring robust connectivity between system modules and external systems. In addition to hardware, the network 128 incorporates software for data management, including packetizing and de-packetizing sensor data, controlling communication protocols, and integrating with cloud platforms for remote access and advanced analytics. The network 128 may also utilize advanced configurations, such as software-defined networking (SDN), to optimize data flow and improve scalability. By enabling real-time data transfer between sensors 122, the processor 112, and user interface 118, the network 128 ensures that insights, such as fault detection and diagnostics, are promptly available. Moreover, the network 128 supports external connectivity, allowing integration with cloud-based systems for data storage, remote monitoring, and predictive analytics.

The load 120 may be a mechanical or movable component that is driven by the motor 110. Depending on the application, the load 120 may be a conveyor belt, pump, fan, or industrial machinery. The system 50 ensures the motor operates efficiently under varying load conditions, monitoring its behavior through the integrated sensors 122. By analyzing data from the sensors, the system 50 may detect anomalies caused by load variations, such as overloads or imbalances.

The power supply 126 provides the necessary electrical energy to operate the motor 110, sensors 122, and the system's 50 control components. The power supply 126 may be configured for alternating current (AC) or direct current (DC) operation, depending on the motor type and application. The power supply 126 ensures stable voltage and current delivery to avoid operational disruptions. In some cases, the power supply 126 may include features like surge protection, voltage regulation, or backup battery systems to enhance reliability.

The motor 110 serves as a component for converting electrical energy into mechanical energy to drive the connected load 120. In some embodiments, the motor may be configured as an induction motor, synchronous motor, or brushless DC motor, depending on the specific application requirements. The motor 110 includes integral components like the rotor 102, which rotates to generate mechanical torque, and the bearings 108, which provide support and facilitate smooth rotational movement while reducing friction. Surrounding the rotor 102 is the stator, which contains the stationary windings that interact with the rotor 102 to produce motion. Sensors 122 are strategically placed within the system 50 to monitor parameters such as vibration, temperature, current, and rotational speed, enabling the detection of potential faults such as misalignments, overheating, or mechanical wear in components like the bearings 108. In some embodiments, the controller 124 processes this sensor data, along with computations from the processor 112.

The sensor/control interface 114 acts as the communication hub between the sensors 122 and the processor 112. As an interface for sensors, the sensor/control interface 114 collects data from various sensors and transmits the data to the processor 112 for analysis. The sensor/control interface 114 may support multiple communication protocols, such as CAN bus, Modbus, or Ethernet, enabling seamless integration with diverse sensor types. In addition, the sensor/control interface 114 ensures accurate synchronization of data collection, reducing latency and improving fault detection efficiency. As an interface for control actions, the sensor/control interface 114 allows the processor 112 to send commands to the controller 124, enabling real-time adjustments in motor operation.

The motor controller 124 controls the operation of the motor 110. For example, the controller 124 may adjust parameters like speed, torque, and direction of rotation of the motor based on inputs from the processor 112 and sensors 122. The controller 124 plays a key role in maintaining motor efficiency and stability, especially under varying load conditions. For advanced applications, the controller 124 may include features such as field-oriented control (FOC) for high-performance motor control or adaptive algorithms for handling dynamic conditions. The controller 124 communicates with the processor 112 via the network 128 to ensure that operational adjustments align with diagnostic insights.

When the fault-detection system 30 determines that a fault is caused based on the sensor signals of the sensors 122 during the operation of the induction machine (induction motor 110), the fault-detection system 30 may transmit a control signal via the network 128 to slow down or stop driving the induction motor 110 based on a preprogrammed algorithm (not shown) stored in the memory 116.

FIG. 1B illustrates a flowchart of a method 150 for motor fault detection, according to some embodiments. FIG. 1B is described with reference to one or more elements from FIG. 1A. At 152, the method 150 comprises acquiring sensor data from a plurality of sensors. As an example, the sensors may include one or a combination of vibration sensors, current sensors, temperature sensors, and acoustic sensors, among others that monitor one or more state parameters of the motor. It may be contemplated that the sensors are not limited to the above-mentioned sensors. Each sensor captures data corresponding to a specific modality, such as mechanical vibrations, thermal characteristics, or electrical current signatures, providing a diverse set of measurements for comprehensive motor monitoring. This data is transmitted to the fault detection system 30 of FIG. 1A for further analysis. In some embodiments, the collected sensor data may be preprocessed to remove outliers and noise. The denoised sensor data may then be normalized to have zero mean and unit variance.

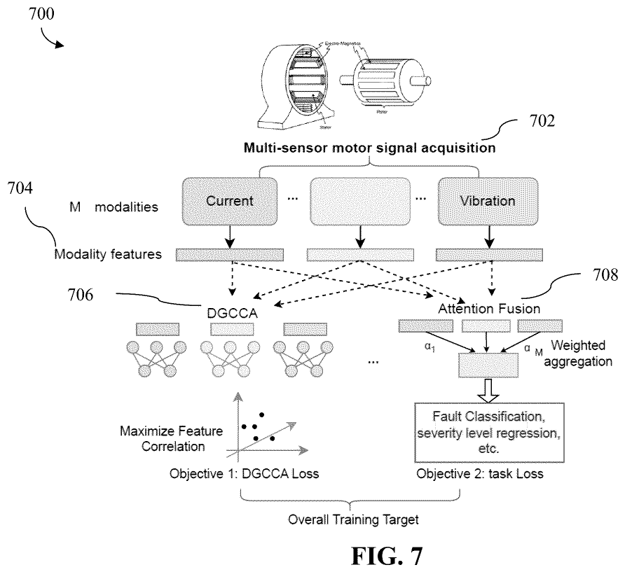

At 154, the system 50 extracts features from each sensor's data from the plurality of sensors using one or more feature extraction models. These models transform the raw data into meaningful representations, such as time-domain features (mean, standard deviation), frequency-domain features (spectral peaks, harmonics), and advanced signal-processing metrics like wavelet coefficients or kurtosis. Feature extraction ensures that the data is formatted and simplified for further computational steps, preserving only the most relevant information. Feature extraction is explained in detail with reference to FIG. 7.

At 156, the extracted features are mapped to a shared latent space using a deep generalized canonical correlation analysis (DGCCA) model. The DGCCA model aligns the features from multiple modalities by learning nonlinear transformations that maximize correlations among the sensor data streams. The DGCCA is explained in detail with reference to FIG. 7. This mapping ensures that data from all sensors is combined into a unified representation, enabling efficient and meaningful multi-modal analysis. At 158, the method 150 comprises applying an attention-based fusion mechanism to the DGCCA-aligned features. The attention mechanism dynamically computes attention weights for each sensor modality, assigning higher importance to the features that are most relevant to the fault detection task. For example, if vibration data shows signs of mechanical issues, it is given a higher weight, while less relevant modalities may be deprioritized. This step ensures that the fused representation emphasizes information.

At step 160, a fused feature representation is generated by aggregating the DGCCA-aligned features, weighted by the attention mechanism. This fused representation provides a comprehensive summary of the motor's condition, integrating data from all sensors into a single vector that captures both individual and collective insights. At 162, the fused feature representation is used to generate motor fault data. The motor fault data may comprise a classification or type of the motor fault. Additionally or alternately, the motor fault data may comprise a fault severity level of the motor fault. In this regard, the processor 112 of the motor fault detection system 30 of FIG. 1A may classify motor faults and/or estimate fault severity levels and thereby generate motor fault data. A machine learning classifier, such as a neural network or support vector machine, analyzes the fused feature representation to identify specific types of motor faults, such as bearing failures, rotor imbalances, or overheating.

Additionally, in some embodiments, the method 150 may further comprise generating one or more control signals for controlling the motor, based on the motor fault data and submitting the control signals to the motor controller 124 of FIG. 1A. The motor controller 124 controls the motor in accordance with the one or more control signals. The one or more control signals may specify values of currents, voltages, or rotation speed of the motor. In some embodiments, the motor may be slowed down or stopped based on the type of the detected fault and/or the severity of the detected fault. Additionally, in some embodiments, the method 150 may further comprise generating one or more alerts based on the generated motor fault data. According to some embodiments, the method 150 may still further comprise generating one or more corrective actions to combat or address the detected fault. The one or more alerts and/or the corrective actions may be rendered through a suitable interface such as the user interface 118 of the fault detection system 30 of FIG. 1A.

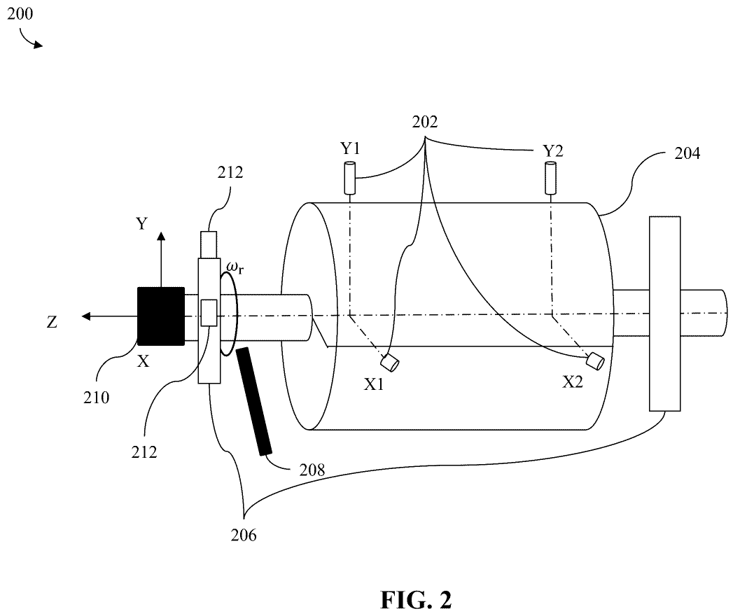

FIG. 2 is an exemplar illustration of an induction motor, according to one embodiment. FIG. 2 illustrates an environment 200 illustrating a motor fault monitoring system designed to detect and analyze potential issues in a motor through the integration of various sensors and components. FIG. 2 shows a rotor 204, air gap sensors 202, one or more acceleration sensors 212, one or more tachometers 208, a load 210 and two bearings 206. The rotor 204 is the central rotating element of the motor, supported by bearings 206 mounted to ensure smooth and stable operation. The bearings 206 minimize friction and provide structural support. However, faults such as misalignment, wear, or cracking in the bearings can lead to vibrations, which may be detected by processing data provided by the acceleration sensors 212 positioned along the x, y, and z axes. These sensors 212 monitor dynamic forces and can help identify imbalances in the rotor 204, looseness in mounts, or excessive vibration caused by resonance. For example, an increase in high-frequency vibrations may indicate bearing wear, while irregular peaks in the vibration spectrum point to looseness.

The tachometer 208 measures the rotating speed of the rotor 204. In some embodiments, two accelerometers may be used as the acceleration sensors 212 to record the motor vibration along horizontal and vertical directions, respectively. In some embodiments, three current probes connected to the terminals of the stator record the three-phase stator current accordingly. The air gap sensors 202, may be strategically placed near the rotor 204, for example at positions X1, X2, Y1, Y2 to measure the air gap between the rotor 204 and the stator (not shown for the sake of avoiding obscuring the figure). A uniform air gap is required for optimal motor performance. Variations in the air gap, such as a different reading at Y1 compared to that at Y2, can indicate rotor 204 eccentricity, thermal deformation, or shaft misalignment. Such faults, if undetected, may lead to rotor-stator contact and severe mechanical damage. A tachometer 208 measures the rotational speed (ωᵣ) of the rotor 204, providing data to detect anomalies such as inconsistent speed, which may indicate load fluctuations, slippage, or electrical faults like winding imbalances.

In some embodiments, the load 210 may be implemented as a powder brake that applies a controlled torque to simulate operational conditions. Monitoring the motor's behavior under different load levels can reveal weaknesses such as increased vibrations due to insufficient lubrication in bearings or overheating caused by mechanical friction. In addition to these mechanical parameters, the system 50 may incorporate electrical and thermal monitoring for comprehensive fault detection. For example, thermal sensors may monitor overheating in specific components, while current and voltage sensors may detect electrical faults such as insulation breakdown or short circuits.

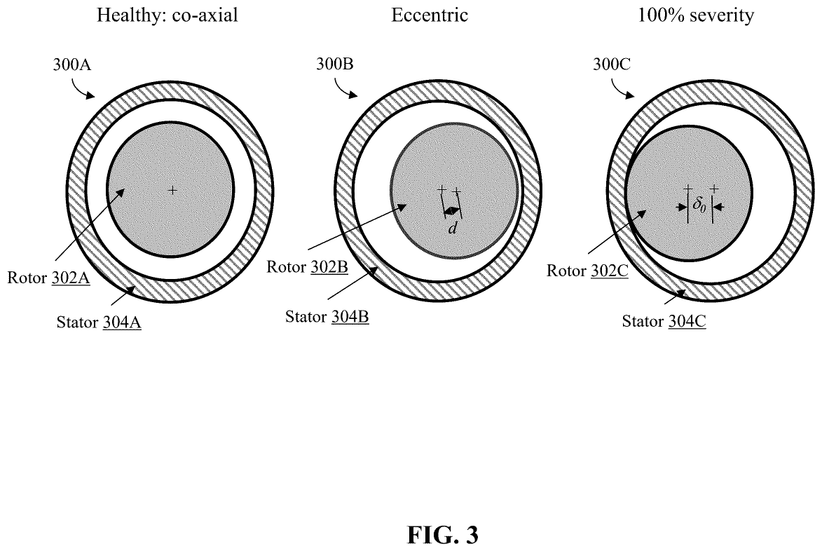

FIG. 3 is a diagram of eccentricity severity level indicated by relative air gap, according to one embodiment. Three cross sectional views of the core of an induction motor are shown. In the motor 300A, the rotor 302A and the stator 304A are co-axial and hence there is direct contact between the rotor and the stator. This corresponds to a healthy rotor-stator configuration. In the motor 300B, the rotor 302B and the stator 304B are not co-axial but the rotor 302B still does not have direct contact with the stator 304B during rotation. This corresponds to an eccentric rotor-stator configuration. In this configuration, the deviation of the centre of rotation of the rotor 302B during one full rotation is measured by the parameter d. In the motor 300C, the rotor 302C and the stator 304C are not co-axial and there is direct contact between the rotor and the stator. This corresponds to a 100% severity level and leads to wear and tear of the stator and the rotor. In this configuration, the deviation of the centre of rotation of the rotor 302C during one full rotation is measured by the parameter δ₀. The eccentricity level y of a motor can thus be expressed as

$$Eccentricity level y = \frac{d}{{δ}_{0}} \times 100 \%$$

where d is the distance between the actual rotor axis and the stator axis, and δ₀ is the average air gap length in the corresponding healthy motor. For ideal healthy induction machines, the rotor and the stator are coaxial, therefore d=0.

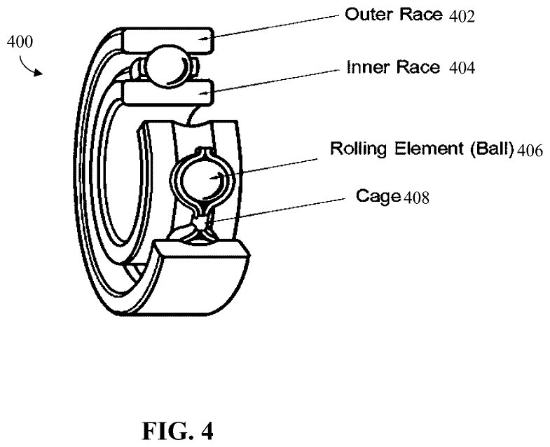

FIG. 4 illustrates a cross sectional view of a rolling-element bearing 400 of an electrical motor, according to one embodiment. The internal components of the rolling-element bearing 400 comprises an outer race 402, an inner race 404, a rolling element 406, and a cage 408. Bearings are components in mechanical systems, used to reduce friction and support radial and axial loads. The outer race 402, which remains stationary, provides a raceway for the rolling elements and interfaces with the housing of the machinery. Surface roughness or damage to the outer race 402 can occur due to factors such as contamination, inadequate lubrication, or excessive loads. For instance, in industrial environments where dust particles mix with the lubricant, abrasive wear on the outer race 402 can lead to pitting or corrosion. The inner race 404 rotates with the shaft and similarly serves as a track for the rolling elements. Damage to the inner race 404 may result from shaft misalignment, vibration, or improper assembly, causing localized wear or spalling. An example of this is seen in misaligned shafts of high-speed motors, where uneven stress distribution damages the inner race.

The rolling elements 406, typically balls or cylinders, reduce friction by rolling between the inner and outer races, distributing the applied load. Defects in the rolling elements 406, such as cracks, pitting, or flat spots, may emerge due to manufacturing flaws, sudden impact loads, or contamination in the lubricant. In high-speed applications, such as turbines, even minor imperfections in the rolling elements 406 may generate vibrations, noise, and accelerated bearing failure. The cage 408, or retainer, is responsible for maintaining proper spacing and alignment of the rolling elements 406, preventing rolling elements 406 from contacting one another. Over time, the cage 408 may experience wear, deformation, or fractures due to operational stress, overheating, or poor lubrication. For instance, bearings used in systems with frequent start-stop cycles often see fatigue-related damage in the cage, leading to erratic vibrations.

Bearing faults can be detected using various techniques. Faults associated with the outer race 402 (also referred to as outer race faults) produce characteristic vibration frequencies that may be identified through vibration analysis. Similarly, faults with the inner race 404 (also referred to as rolling element faults) generate different defect frequencies, often pinpointed using advanced signal processing methods such as envelope detection. Faults with the rolling elements 406 (also referred to as rolling element faults) create repetitive impact forces, detectable through high-frequency vibration analysis or acoustic emission sensors. Faults with the cage 408 (also referred to as cage faults), on the other hand, lead to erratic vibrations and noise, and overheating issues related to cage deformation can be identified using infrared thermography. Preventive measures, such as proper lubrication, the use of sealed or shielded bearings to prevent contamination, and condition monitoring techniques like vibration analysis or thermography, play a role in extending bearing life and minimizing downtime.

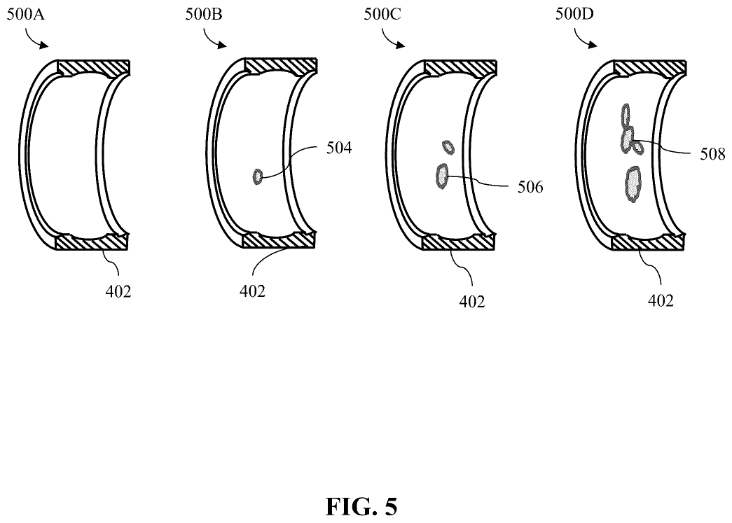

FIG. 5 illustrates various levels of bearing surface roughness severity of a bearing that supports the rotor shaft of an induction motor, according to one embodiment. FIG. 5 shows progressive levels of surface roughness severity on the bearing surface for example the outer race 402, which supports the rotor shaft of an induction motor. FIG. 5 highlights different stages (500A-500D) of degradation that occur over time due to operational and environmental factors such as stress, contamination, or insufficient maintenance. In the first depiction 500A, the outer race 402 appears smooth and intact, signifying an undamaged or new bearing surface. Bearings in this condition facilitate optimal rotation of the rotor shaft with minimal friction and no irregular vibrations. In the second depiction 500B, minor surface roughness at spot 504 is observed on the outer race 402, likely caused by initial stages of wear or contamination. Such defects arise when small abrasive particles infiltrate the lubricant, leading to localized scratches or dents. Though minor, this level of roughness may begin to affect the bearing's performance by generating slight vibrations. Early-stage roughness can be addressed by improving lubrication or filtering contaminants.

The third illustration 500C shows a more advanced stage of degradation at spot 506, where pitting and multiple imperfections are present on the outer race 402. The spot 506 is the surface roughness present on the outer race 402. This level of damage may be typically caused by fatigue, where repeated cyclic loads result in the formation of pits or cracks. Bearings in this condition often generate increased vibration levels, leading to noise and reduced motor efficiency. For example, in heavy-duty applications such as conveyor belt motors, prolonged exposure to heavy loads without proper lubrication can accelerate this form of wear.

The final illustration 500D represents severe surface roughness at spot 508, characterized by extensive damage across the outer race 402. This stage of wear may be the result of prolonged operation under extreme conditions, such as excessive loads, high speeds, or inadequate maintenance. Severe roughness lead to spalling, where larger sections of the bearing material flake away, causing failure of the bearing. In this state, the induction motor's rotor shaft is likely to experience misalignment, excessive heat generation, and mechanical noise, potentially leading to catastrophic system failure. Monitoring and diagnosing these stages of bearing degradation may be achieved using advanced condition-monitoring techniques such as vibration analysis, acoustic emission sensors, and infrared thermography. For instance, vibration analysis may detect specific fault frequencies associated with outer race damage, while thermography may identify heat patterns caused by increased friction. Preventive measures such as ensuring proper lubrication, maintaining cleanliness to avoid contamination, and periodically inspecting bearings for early signs of wear are required to mitigate these issues.

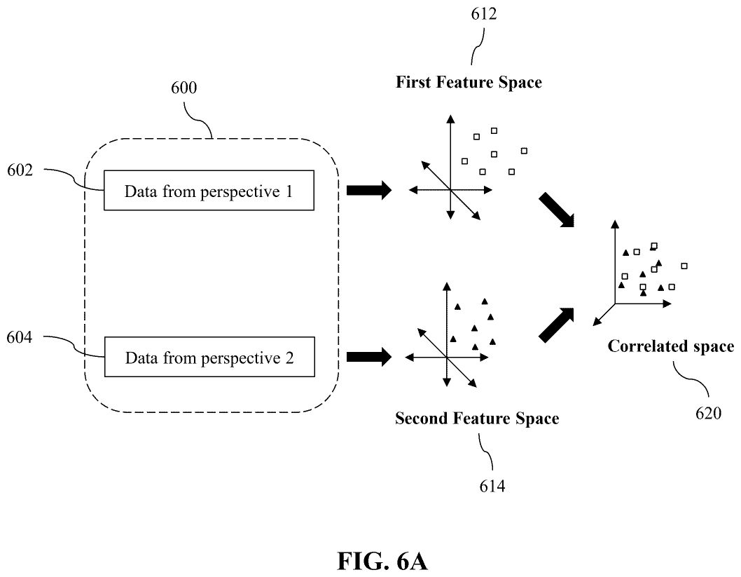

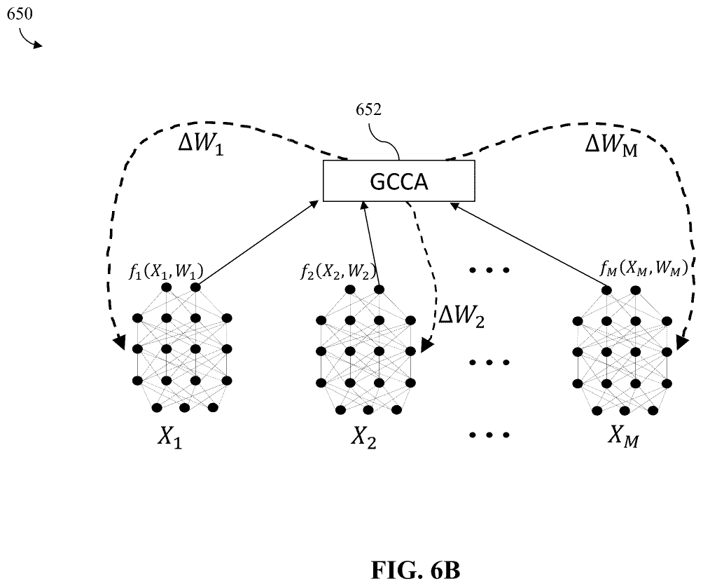

FIG. 6A shows a schematic description of real-world multi-view data, according to some embodiments. In the embodiment shown in FIG. 6A, the multi-view data 600 includes a first multimodal dataset 602 and a second multimodal dataset 604. The two datasets 602 and 604 may correspond to the same object but captured from different perspectives or views. For example, the dataset 602 may comprise data captured from a perspective 1 while the dataset 604 may comprise data captured from a perspective 2. The perspectives 1 and 2 may differ in terms of at least one parameter in each modality. For example, in the image modality, the perspective 1 may correspond to taking a picture of an object from a first angle while the perspective 2 may correspond to taking a picture of the same object from a second angle. Additionally, in the modality of language, the perspective 1 may correspond to a description of an object expressed in a first language while the perspective 2 may correspond to a description of the object expressed in a second language. The representations from different perspectives can be treated as different views. The multi-view data are of different modalities, but correlated to each other when projected in the feature space. The first multimodal dataset 602 may be projected in a first feature space 612 while the second multimodal dataset 604 may be projected in a second feature space 614. A correlated feature space 620 may be defined based on the correlation between the two datasets 602 and 604.

FIG. 6B is a schematic diagram of a deep nueral network 650 trained to correlate multi-view data in the feature space via generalized canonical correlation analysis, according to some embodiments. The DGCCA module 652 passes the input vectors Xₘ (m=1, . . . , M) in each of M views through multiple layers of nonlinear transformations into feature spaces fₘ (Xₘ) and backpropagates the gradient of the GCCA objective with respect to network parameters Wₘ to tune each view's network parameters by ΔWₘ such that the GCCA reconstruction error among their outputs is minimized. The learned network for each view are then used to test new multi-view data for fault detection. The termination condition includes a condition specifying that the reconstruction error for each view's output is less than or equal to a threshold.

### Canonical Correlation Analysis

Given two sets of vectors X∈ [symbol] ^{d}^{₁}^{×N} and Y∈ [symbol] ^{d}^{₂}^{×N}, where N denotes the number of vectors CCA learns two linear transformations A∈ [symbol] ^{d}^{₁}^{×r} and B∈ [symbol] ^{d}^{₂}^{×r} such that the correlation between A^{T}X and B^{T}Y is maximized. Denote the covariances of X and Y as S₁₁ and S₂₂ respectively, and their cross-covariances as S₁₂. The CCA objective is to solve

$${A}^{*} , {B}^{*} = arg {max}_{A , B} corr ( {A}^{T} X , {B}^{T} Y ) = arg {max}_{A , B} \frac{{A}^{T} {S}_{12} B}{\sqrt{{A}^{T} {S}_{11} A} \sqrt{{B}^{T} {S}_{22} B}} \qquad ( 1 )$$

The above optimization problem can be solved in multiple ways. Let

$$Z {=}^{△} {S}_{11}^{- \frac{1}{2}} {S}_{12} {S}_{22}^{- \frac{1}{2}} ,$$

and the Singular Value Decomposition (SVD) of Z be Z=USV^{T}. Then A*, B*, and the total maximum canonical correlation can be achieved as

$${A}^{*} = {S}_{11}^{- \frac{1}{2}} U \qquad ( 2 )$$

$${B}^{*} = {S}_{22}^{- \frac{1}{2}} V$$

$$corr ( {A}^{* T} , {B}^{* T} Y ) = {trace ( {Z}^{T} Z )}^{\frac{1}{2}} .$$

One limitation of CCA is that it only considers linear transformations. Deep CCA follows the idea of CCA and learns non-linear transformations using a pair of neural networks.

### Deep Canonical Correlation Analysis (Deep CCA)

Let f and g denote two independent neural networks respectively, the objective of deep CCA is to optimize parameters θ_{f}, θ_{g} of f, g such that the canonical correlation between the output of f and g, denoted as F_{X}=f(X;θ_{f}) and F_{Y}=g(Y;θ_{g}), can be maximized by finding two linear transformation C*, D*. The objective of deep CCA is to achieve

$$\{ {θ}_{f}^{*} , {θ}_{g}^{*} \} = arg {max}_{\{ {θ}_{f} , {θ}_{g} \}} CCA ( {F}_{X} , {F}_{Y} ) = arg {max}_{\{ {θ}_{f} , {θ}_{g} \}} corr ( {C}^{* T} {F}_{X} , {D}^{* T} {F}_{Y} ) \qquad ( 3 )$$

In order to update {θ_{f}, θ_{g}}, a loss for measuring the canonical correlation should be calculated and back propagated. Similar to CCA, let R₁₁ and R₂₂ be covariances of F_{X} and F_{Y}, respectively, and their cross covariance as R₁₂. Define matrix

$$E {=}^{△} {R}_{11}^{- \frac{1}{2}} {R}_{12} {R}_{22}^{- \frac{1}{2}} .$$

According to (2), the canonical correlation loss for updating F_{X}, F_{Y} can be defined by

$${ℒ}_{CCA} = - {trace ( {E}^{T} E )}^{\frac{1}{2}} \qquad ( 4 )$$

Network parameters of f(X;θ_{f}) and g (Y;θ_{g}) can be updated by minimizing the CCA loss [symbol] _{CCA} in the above equation (4).

FIG. 7 is a diagram illustrating a framework 700 for multi-sensor motor fault detection, according to one embodiment. The framework aims to extract, align, and fuse features from multiple sensory inputs to improve downstream task performance. The framework 700 comprises multi-sensor motor signal acquisition operations 702 where signals from multiple sensors such as current sensors, vibration sensors and the like are acquired by a processor. The signals acquired by multiple sensors (current, vibration, etc.) from motor are then processed to extract modality features 704. In this regard, some embodiments consider two distinct preprocessing approaches tailored to the specific characteristics of the datasets under investigation. In the first approach, the model is directly fed with raw time series sensory inputs collected to extract time-domain features. This approach is justified by the non-periodic nature of some fault features, such as fault feature induced by bearing friction or insulation, which can be more effectively captured in the time domain. In the second approach, frequency-domain features are extracted by transforming the raw time-domain sensory data into a spectral representation before feeding them to the model. This approach is preferable for periodic fault features, such as that caused by motor eccentricity, which manifest as a frequency-domain signature. The raw time-domain data is organized in a matrix where each column represents a distinct channel of sensory measurements. For each channel, we apply the Discrete Fourier Transform (DFT) to convert the time-domain signals into their corresponding frequency-domain representations.

Let x(t) denote the discrete N-point time series data, where t=1, . . . , T. To focus on the most relevant frequencies, in some embodiments the frequency is limited to a Type equation here. configurable upper threshold (e.g. 4096 Hz). The magnitude values are converted to a logarithmic scale (dB) to compress the dynamic range and highlight significant features in the spectrum. The frequency spectrum of x (t) may be expressed as X(k)=20·

$${log}_{10} ( \vert DFT ( x ( t ) ) \vert ) .$$

Let xₘ∈R^{t}^{ₘ}^{×N} denote a set of vectors (in the time domain or frequency domain) collected by the mth(m=1, . . . , M) sensor, where N is the total number of measurements. Each xₘ is passed through a corresponding feature extractor (for example, 1D-ResNet model for time series input and 2D-ResNet for frequency spectrum input) to obtain the feature representations

$${\{ {X}_{m} = {Φ}_{m} ( {x}_{m} ) \}}_{m = 1}^{M} .$$

The extracted modality features 704 are fed into the DGCCA module 706 to maximize feature correlation in a shared latent space. The DGCCA network processes the features to align them in the shared latent space. The DGCCA network comprises multiple fully connected layers that map the feature representations

$${\{ {X}_{m} = {Φ}_{m} ( {x}_{m} ) \}}_{m = 1}^{M}$$

to the DGCCA outputs

$${\{ {Z}_{m} \}}_{m = 1}^{M} ∈ {R}^{{o}_{m} \times N} .$$

Instead of maximizing the canonical correlation between output pairs, DGCCA aims to find a shared latent space G among the output of neural networks of m different views/modalities by minimizing a loss function via an optimization problem

$$minimize {U}_{m} ∈ {R}^{{o}_{m} \times r} , G ∈ {R}^{r \times N} \qquad ( 5 )$$

$${L}_{DGCCA} = {\sum }_{m = 1}^{M} {‖ G - {U}_{m}^{T} {Z}_{m} ‖}_{F}^{2}$$

$$s . t . {GG}^{T} = {I}_{r}$$

where G∈R^{r×N} is the shared representation we are interested in learning, Uₘ represents the mth linear transformation, oₘ is the dimensionality of the mth view, r is the dimensionality of the learned representation, and Iᵣ∈R^{r×r} is an identity matrix.

In order to train the neural networks in DGCCA, the gradient of the GCCA objective is computed with respect to any one of its input views. For each view's output covariance matrices

$${\{ {C}_{m , m} = {Z}_{m} {Z}_{m}^{T} \}}_{m = 1}^{M}$$

are computed. Subsequently, projection matrices

$${\{ {P}_{m} = {Z}_{m}^{T} {C}_{m , m}^{- 1} {Z}_{m} \}}_{m = 1}^{M}$$

are derived from these covariance matrices. The sum projection matrix P̅ aggregates the individual projection matrices:

$$\overline{P} = {\sum }_{m = 1}^{M} {P}_{m}$$

Then the top r eigenvectors of P̅ are computed and the DGCCA loss L_{DGCCA} is derived based on the eigenvalues of P̅. This loss function ensures that the DGCCA outputs are maximally aligned in the shared subspace.

An attention fusion mechanism 708 combining the correlated features and the weighted aggregation is used for fault detection and severity estimation tasks. After obtaining the DGCCA-aligned features, the attention-based mechanism 708 may be applied to fuse the aligned features effectively. Specifically, the attention-based fusion mechanism 708 may compute attention weights for each feature representation, capturing the relative importance of different sensor modalities. The fused feature representation F is obtained by taking a weighted sum of the DGCCA-aligned features, where the weights are derived from the attention mechanism. This step ensures that the most informative features from each sensor are emphasized, leading to a more robust and discriminative fused representation.

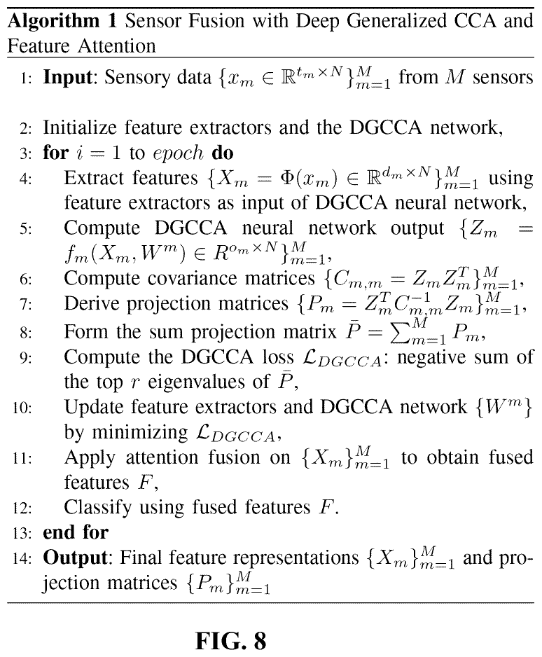

FIG. 8 shows a sensor fusion algorithm using the deep generalized canonical correlation analysis and attention fusion, according to one embodiment.

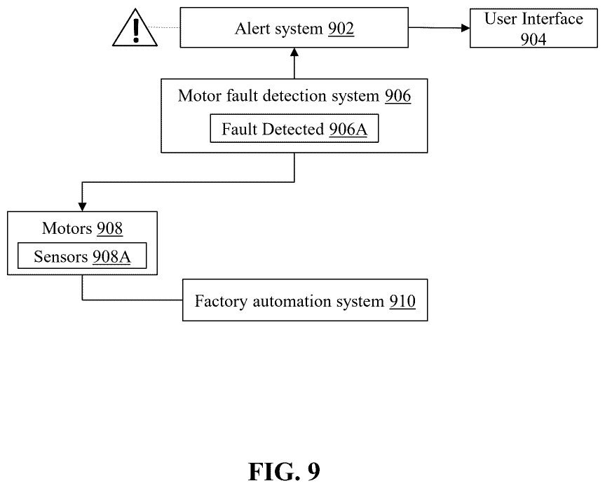

FIG. 9 is a diagram that illustrates a use case for motor fault detection in a factory automation system 910, according to one embodiment. The motor fault detection system 906 continuously monitors the performance and health of motors 908 through associated sensors 908A. The sensors 908A may include vibration sensors, temperature sensors, current sensors, or acoustic emission sensors, that generate measurement data indicative of motor faults. For instance, the motor fault detection system 906 may utilize a vibration sensor to identify unusual patterns in the rotor's movement, or a temperature sensor to detect overheating due to increased friction or electrical issues.

The motor fault detection system 906 upon identifying a fault, may trigger an alert within the alert system 902. The alert system 902 ensures that factory operators or supervisors are promptly informed about potential or ongoing faults. Alerts may be generated in various formats, such as visual signals on a control panel, auditory alarms, or digital notifications sent via connected devices. For instance, in a smart factory setup, an alert may be sent to an operator's mobile device or the central control room, facilitating immediate intervention.

The alert system 902 may also communicate directly with the user interface 904, which serves as a platform for operators to view detailed fault diagnostics. The user interface 904 may display information, such as the fault's nature or type, severity level, location, and suggested corrective actions. For example, the alert system 902 may indicate that an abnormal vibration in a motor's bearing has been detected, along with recommendations to inspect or replace the bearing. The factory automation system 910 may integrate these fault detection capabilities into the broader industrial workflow. In some embodiments, when faults are detected, the factory automation system 910 may take automated corrective actions to prevent further damage or disruption. For instance, the alert system 902 may shut down the affected motor, reroute processes to backup machinery, or adjust production schedules to minimize downtime. The combination of motors 908, sensors 908A, and the motor fault detection system 906 ensures a seamless and intelligent fault management process for the factory automation system 910. This setup enhances operational efficiency, minimizes unplanned downtimes, and extends the lifecycle of machinery.

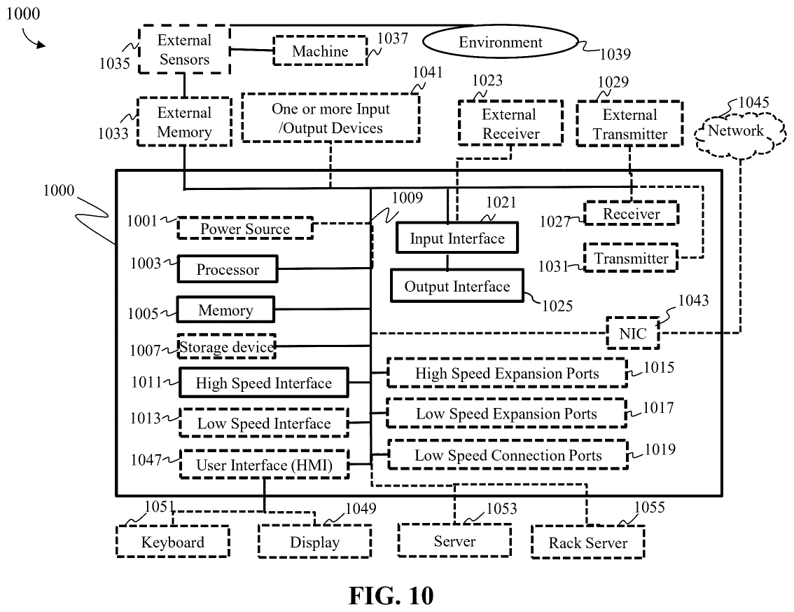

FIG. 10 shows a schematic diagram of some components of a control system 1000 for motor fault detection in a motor, in accordance with some embodiments. The control system 1000 includes a power source 1001, a processor 1003, a memory 1005, a storage device 1007, all connected to a bus 1009. Further, a high-speed interface 1011, a low-speed interface 1013, high-speed expansion ports 1015 and low speed connection ports 1017, can be connected to the bus 1009. In addition, a low-speed expansion port 1019 is in connection with the bus 1009. Further, an input interface 1021 can be connected via the bus 1009 to an external receiver 1023 and an output interface 1025. A receiver 1027 can be connected to an external transmitter 1029 and a transmitter 1031 via the bus 1009. Also connected to the bus 1009 can be an external memory 1033, external sensors 1035, machine(s) 1037, and an environment 1039. Further, one or more external input/output devices 1041 can be connected to the bus 1009. A network interface controller (NIC) 1043 can be adapted to connect through the bus 1009 to a network 1045, wherein data or other data, among other things, can be rendered on a third-party display device, third party imaging device, and/or third-party printing device outside of the control system 1000.

The memory 1005 may store instructions that are executable by the control system 1000 and any data that can be utilized by the methods and systems of the present disclosure. The memory 1005 can include random access memory (RAM), read only memory (ROM), flash memory, or any other suitable memory systems. The memory 1005 can be a volatile memory unit or units, and/or a non-volatile memory unit or units. The memory 1005 may also be another form of computer-readable medium, such as a magnetic or optical disk.

The storage device 1007 can be adapted to store supplementary data and/or software modules used by the control system 1000. The storage device 1007 can include a hard drive, an optical drive, a thumb-drive, an array of drives, or any combinations thereof. Further, the storage device 1007 can contain a computer-readable medium, such as a floppy disk device, a hard disk device, an optical disk device, or a tape device, a flash memory or other similar solid-state memory device, or an array of devices, including devices in a storage area network or other configurations. Instructions can be stored in an information carrier. The instructions, when executed by one or more processing devices (for example, the processor 1003), perform one or more methods, such as those described above.

The control system 1000 can be linked through the bus 1009, optionally, to a display interface or user Interface (HMI) 1047 adapted to connect the system 1000 to a display device 1049 and a keyboard 1051, wherein the display device 1049 can include a computer monitor, camera, television, projector, or mobile device, among others. In some implementations, the system 1000 may include a printer interface to connect to a printing device, wherein the printing device can include a liquid inkjet printer, solid ink printer, large-scale commercial printer, thermal printer, UV printer, or dye-sublimation printer, among others.

The high-speed interface 1011 manages bandwidth-intensive operations for the control system 1000, while the low-speed interface 1013 manages lower bandwidth-intensive operations. Such allocation of functions is an example only. In some implementations, the high-speed interface 1011 can be coupled to the memory 1005, the user interface (HMI) 1045, and to the keyboard 1051 and the display 1049 (e.g., through a graphics processor or accelerator), and to the high-speed expansion ports 1015, which may accept various expansion cards via the bus 1009. In an implementation, the low-speed interface 1013 is coupled to the storage device 1007 and the low-speed expansion ports 1017, via the bus 1009. The low-speed expansion ports 1017, which may include various communication ports (e.g., USB, Bluetooth, Ethernet, wireless Ethernet) may be coupled to the one or more input/output devices 1041. The control system 1000 may be connected to a server 1053 and a rack server 1055. The control system 1000 may be implemented in several different forms. For example, the control system 1000 may be implemented as part of the rack server 1055.

The above description provides exemplary embodiments only, and is not intended to limit the scope, applicability, or configuration of the disclosure. Rather, the above description of the exemplary embodiments will provide those skilled in the art with an enabling description for implementing one or more exemplary embodiments. Contemplated are various changes that may be made in the function and arrangement of elements without departing from the spirit and scope of the subject matter disclosed as set forth in the appended claims.

Specific details are given in the above description to provide a thorough understanding of the embodiments. However, understood by one of ordinary skill in the art can be that the embodiments may be practiced without these specific details. For example, systems, processes, and other elements in the subject matter disclosed may be shown as components in block diagram form in order not to obscure the embodiments in unnecessary detail. In other instances, well-known processes, structures, and techniques may be shown without unnecessary detail in order to avoid obscuring the embodiments. Further, like reference numbers and designations in the various drawings indicated like elements.

Also, individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process may be terminated when its operations are completed but may have additional steps not discussed or included in a figure. Furthermore, not all operations in any particularly described process may occur in all embodiments. A process may correspond to a method, a function, a procedure, a subroutine, a subprogram, etc. When a process corresponds to a function, the function's termination can correspond to a return of the function to the calling function or the main function.

Furthermore, embodiments of the subject matter disclosed may be implemented, at least in part, either manually or automatically. Manual or automatic implementations may be executed, or at least assisted, through the use of machines, hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

Various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine. Typically, the functionality of the program modules may be combined or distributed as desired in various embodiments.

Embodiments of the present disclosure may be embodied as a method, of which an example has been provided. The acts performed as part of the method may be ordered in any suitable way. Accordingly, embodiments may be constructed in which acts are performed in an order different than illustrated, which may include performing some acts concurrently, even though shown as sequential acts in illustrative embodiments. Although the present disclosure has been described with reference to certain preferred embodiments, it is to be understood that various other adaptations and modifications can be made within the spirit and scope of the present disclosure. Therefore, it is the aspect of the append claims to cover all such variations and modifications as come within the true spirit and scope of the present disclosure.

What is claimed is:

1. A method for motor fault detection, comprising:
acquiring sensor data from each sensor of a plurality of sensors associated with a motor, wherein each sensor of the plurality of sensors provides data corresponding to a unique modality of a plurality of modalities;
extracting features from the sensor data of each sensor of the plurality of sensors using one or more feature extraction models;
mapping the extracted features to a shared latent space using at least one Deep Generalized Canonical Correlation Analysis (DGCCA) model, wherein the at least one DGCCA model aligns the features by learning nonlinear transformations that maximize correlations among the sensor data of different sensors of the plurality of sensors;
applying an attention-based fusion mechanism to the DGCCA-aligned features to dynamically compute attention weights for each sensor modality of the plurality of modalities based on a relevance of a respective sensor modality to a fault detection task;
generating a fused feature representation by aggregating the DGCCA-aligned features weighted by the attention-based fusion mechanism; and
generating motor fault data based on the fused feature representation.

2. The method of claim 1, further comprising:
generating one or more control signals, based on the motor fault data, wherein the one or more control signals specify values of one or more operational parameters of the motor; and
controlling the motor, based on the one or more control signals.

3. The method of claim 1, wherein extracting the features from the sensor data of each sensor of the plurality of sensors further comprises:
extracting time-domain features for non-periodic faults; and
extracting frequency-domain features using Discrete Fourier Transform (DFT) for periodic faults.

4. The method of claim 1, wherein the at least one DGCCA model aligns features from two or more sensor modalities of the plurality of modalities, wherein the plurality of modalities include at least vibration, current, and velocity.

5. The method of claim 1, wherein the attention-based fusion mechanism assigns weights to sensor modalities according to their relative importance to the fault detection task.

6. The method of claim 1, further comprising:
preprocessing the sensor data to remove noise and normalizing the preprocessed data to have zero mean and unit variance.

7. The method of claim 1, wherein generating the motor fault data comprises at least one of:
classifying, using a neural network, motor faults associated with the motor; or
predicting, using the neural network, fault severity levels associated with the motor faults associated with the motor.

8. The method of claim 1, wherein the plurality of sensors comprises at least two of vibration sensors, current sensors, velocity sensors, or air gap sensors.

9. The method of claim 1, wherein mapping the extracted features to a shared latent space further comprises aligning each feature of the extracted features into a plurality of fault-specific latent spaces using a plurality of DGCCA models, wherein each DGCCA model of the plurality of DGCCA models aligns the extracted feature into a unique fault-specific latent space of the plurality of fault-specific latent spaces.

10. The method of claim 9, wherein the attention-based fusion mechanism comprises a plurality of attention networks, each attention network of the plurality of attention networks corresponding to a specific DGCCA model of the plurality of DGCCA models and a specific fault type, and each attention network of the plurality of attention networks dynamically computing attention weights based on the aligned features of a corresponding fault type.

11. The method of claim 1, wherein mapping the extracted features to a shared latent space further comprises:
using one DGCCA model to align features from all sensor modalities into a shared latent space, wherein the aligned features are used for detecting multiple fault types.

12. The method of claim 11, wherein the attention-based fusion mechanism comprises:
a multi-head attention network, wherein each attention head of the multi-head attention network corresponds to a specific fault type, and wherein each attention head of the multi-head attention network dynamically assigns weights to the aligned features based on the fault type being analyzed.

13. A system for motor fault detection, comprising:
memory configured to store a feature extraction model, a Deep Generalized Canonical Correlation Analysis (DGCCA) model, an attention-based fusion model, and computer-executable instructions;
at least one processor configured to execute the instructions to:
acquire sensor data from each sensor of a plurality of sensors configured to collect multi-modal data from a motor, wherein each sensor of the plurality of sensors provides data corresponding to a unique modality of a plurality of modalities;
extract, using the feature extraction model, features from the sensor data of each sensor of the plurality of sensors;
align, using the DGCCA model, the extracted features into a shared latent space by learning nonlinear transformations that maximize correlations among the sensor data of different sensors of the plurality of sensors;
dynamically assign, using the attention-based fusion model, attention weights to the DGCCA-aligned features based on their relevance to a fault detection task;
generate a fused feature representation by aggregating the DGCCA-aligned features weighted by the attention-based fusion model; and
generate motor fault data based on the fused feature representation.

14. The system of claim 13, wherein the at least one processor is further configured to:
generate one or more control signals, based on the motor fault data, wherein the one or more control signals specify values of one or more operational parameters of the motor; and
control the motor, based on the one or more control signals.

15. The system of claim 13, wherein to extract the features from the sensor data of each sensor of the plurality of sensors, the at least one processor is further configured to:
extract time-domain features for non-periodic faults; and
extract frequency-domain features using Discrete Fourier Transform (DFT) for periodic faults.

16. The system of claim 13, wherein the DGCCA model aligns features from two or more sensor modalities of the plurality of modalities, wherein the plurality of modalities include at least vibration, current, and velocity.

17. The system of claim 13, wherein to generate the motor fault data the at least one processor is configured to execute a neural network to perform at least one of:
classification of motor faults associated with the motor; or
prediction of fault severity levels associated with the motor faults associated with the motor.

18. The system of claim 13, wherein to align the extracted features to a shared latent space the at least one processor is configured to align each feature of the extracted features into a plurality of fault-specific latent spaces using a plurality of DGCCA models, wherein each DGCCA model of the plurality of DGCCA models aligns the extracted feature into a unique fault-specific latent space of the plurality of fault-specific latent spaces.

19. The system of claim 18, wherein the attention-based fusion model comprises a plurality of attention networks, each attention network of the plurality of attention networks corresponding to a specific DGCCA model of the plurality of DGCCA models and a specific fault type, and each attention network of the plurality of attention networks dynamically computing attention weights based on the aligned features of a corresponding fault type.

20. A non-transitory computer-readable medium storing instructions that, when executed by a processor, cause the processor to perform a method for motor fault detection, the method comprising:
acquiring sensor data from each sensor of a plurality of sensors associated with a motor, wherein each sensor of the plurality of sensors provides data corresponding to a unique modality of a plurality of modalities;
extracting features from the sensor data of each sensor of the plurality of sensors using one or more feature extraction models;
mapping the extracted features to a shared latent space using at least one Deep Generalized Canonical Correlation Analysis (DGCCA) model, wherein the at least one DGCCA model aligns the features by learning nonlinear transformations that maximize correlations among the sensor data of different sensors of the plurality of sensors;
applying an attention-based fusion mechanism to the DGCCA-aligned features to dynamically compute attention weights for each sensor modality of the plurality of modalities based on a relevance of a respective sensor modality to a fault detection task;
generating a fused feature representation by aggregating the DGCCA-aligned features weighted by the attention-based fusion mechanism; and
generating motor fault data based on the fused feature representation.
